(19) United States
(12) Patent Application Publication
(10) Pub. No.: US 2012/0137775 A1
(43) Pub. Date: Jun. 7, 2012

(54) PIEZOELECTRIC RESONATING DEVICE, MANUFACTURING METHOD THEREOF, PIEZOELECTRIC RESONATOR, AND PIEZOELECTRIC OSCILLATOR

(75) Inventor: Akinori YAMADA, Ina (JP)

(73) Assignee: SEIKO EPSON CORPORATION, Tokyo (JP)

(21) Appl. No.: 13/308,929

(22) Filed: Dec. 1, 2011

(30) Foreign Application Priority Data
Dec. 2, 2010 (JP) 2010-269063

(51) Int. Cl. G01P 3/48; H01L 41/22; H01L 41/107; H01L 41/04; H01L 41/053

(52) U.S. Cl. 73/504.16; 310/370; 310/344; 310/318; 29/25.35

(57) ABSTRACT

A piezoelectric substrate includes rod-shaped resonating arms; a base portion that connects one set of end portions of the respective resonating arms; weight portions which are formed on the other end portions of the respective resonating arms and which have a width larger than that of the respective resonating arms; and groove portions which are formed on each of the front and rear surfaces along the center line of vibration of the respective resonating arms. The piezoelectric substrate also includes excitation electrodes which are formed on each of the front and rear surfaces of the respective resonating arms including the inner side of the respective groove portions. A plurality of frequency adjustment slits extending in a straight line form along the longitudinal direction of the respective resonating arms are formed on the respective weight portions so as to penetrate through the front and rear surfaces of the weight portions.

### BACKGROUND

1. Technical Field

The present invention relates to a piezoelectric resonating device, a method of manufacturing the piezoelectric resonating device, a piezoelectric resonator, and a piezoelectric oscillator.

2. Related Art

In the related art, piezoelectric resonators, for example, tuning-fork type quartz crystal resonators have been known. The tuning-fork type quartz crystal resonators are used, for example, in a reference frequency source of a timepiece or an angular velocity sensor of a piezoelectric gyro apparatus, and miniaturization of an electronic apparatus or the like having these resonators is progressing. In line with this, miniaturization of the piezoelectric resonator is also demanded.

The vibration frequency of the tuning-fork type piezoelectric resonator is proportional to the width of a resonating arm and is inversely proportional to the square of the length thereof. In order to miniaturize the piezoelectric resonator, it is necessary to decrease the length of the resonating arm and decrease the width of the resonating arm. However, when the piezoelectric resonator is configured in such a way, a high-order vibration mode is likely to occur, and the vibration mode tends to become unstable.

In order to suppress the occurrence of a high-order vibration mode and obtain a stable vibration state, JP-A-2009-201162 discloses a piezoelectric resonating device (quartz crystal resonating device) in which a weight portion (balance head) having a larger width than the width of an arm portion of a resonating arm is formed on a distal end portion of the resonating arm of the piezoelectric resonating device. As shown in a plan view of FIG. 13, this tuning-fork type piezoelectric resonating device has a configuration in which an approximately rectangular hole portion is formed in the weight portion which is formed in the distal end portion of the resonating arm. A piezoelectric resonating device 150 includes a pair of narrow rod-shaped resonating arms 170 which protrude in parallel from one end of the base portion 180 thereof, and an approximately rectangular weight portion 160 having a larger width than the width of an arm portion 171 of the resonating arm 170 is formed to be continous to the distal end portion in the longitudinal direction of each of the resonating arms 170. The pair of resonating arms 170 have the same shape. Each of the weight portions 160 is horizontally symmetrical about a center line of vibration B of each of the resonating arms 170, and a groove portion 172 is formed in the arm portion 171 along the center line of vibration B. The groove portion 172 is also symmetrical about the center line of vibration B.

An approximately rectangular hole portion 163 is formed in the central portion in the width direction of the weight portion 160 so as to penetrate from the front surface to the rear surface. The hole portion 163 is a through-hole for connecting electrodes formed on the front and rear surfaces of the piezoelectric resonating device 150. The hole portion 163 is positioned on the extension line of the center line of vibration B the resonating arms 170 and is symmetrical about the center line of vibration B.

FIG. 14 is a plan view showing a modified example of the weight portion 160 of the piezoelectric resonating device 150. A pair of protruding portions 166 protrude from two corner portions of the weight portion 160 toward the base portion 180 shown in FIG. 13 so as to extend along the arm portion 171 while being separated from the arm portion 171. The two protruding portions 166 have the same shape.

JP-A-2010-2430 discloses a resonating gyro device. As shown in FIG. 15, the resonating gyro device includes a base portion 200 positioned at the center, a pair of detection resonating arms 211a and 211b protruding in a straight line form from the central portion of the upper and lower ends of the base portion 200, a pair of connecting arms 213a and 213b extending from the central portions of the left and right ends of the base portion 200 in a direction orthogonal to the detection resonating arms 211a and 211b, respectively, and a pair of driving resonating arms 214a and 214b and 215a and 215b protruding from the distal end portions of the respective connecting arms in a vertical direction orthogonal to the connecting arms. The resonating gyro device also includes two sets of beams 220a and 220b and 221a and 221b extending in an L-shaped form from the respective corner portions of the base portion 200 and supporting portions 222a and 222b that connect the distal end portions of the beams 220a and 220b and the distal end portions of the beams 221a and 221b. The beams 220a, 220b, 221a, and 221b and the supporting portions 222a and 222b are provided on the same surface. The supporting portions 222a and 222b are disposed between the driving resonating arms on the outer side of the detection resonating arms in the extension direction of the detection resonating arms.

In JP-A-2009-201162, it is described that since the weight portion is formed in the distal end portion of the arm portion, it is possible to miniaturize the piezoelectric resonating device and obtain a stable vibration frequency. However, the shape of a piezoelectric vibration substrate is not identical to but is slightly different from the designed shape due to an unevenness in the concentration of an etching solution, temperature, etching time, and the like when forming the piezoelectric vibration substrate by photolithography and etching methods. When a piezoelectric resonating device is formed with such a piezoelectric vibration substrate, the vibration frequency thereof may deviate from a predetermined frequency.

Moreover, JP-A-2010-2430 discloses a resonating gyro device which includes a pair of detection resonating arms extending in a straight line form from the base portion toward both sides thereof, a pair connecting arms extending from the base portion, and a pair of driving resonating arms extending from the distal end portions of the respective connecting arms in a direction orthogonal to the connecting arms toward both sides thereof. However, when a piezoelectric substrate for the resonating gyro device is formed by photolithography and etching methods, it is difficult to obtain a piezoelectric substrate for the resonating gyro device having the same shape as designed due to an unevenness in etching time or the like. Thus, desired properties are not obtained.

### SUMMARY

An advantage of some aspects of the invention is that it provides a piezoelectric resonating device, a resonating gyro device, and a manufacturing method thereof capable of suppressing a frequency unevenness of the piezoelectric resonating device and the resonating gyro device even when a piezoelectric substrate is over-etched due to an unevenness in etching time or the like.

### Application Example 1

This application example of the invention is directed to a piezoelectric resonating device including: a plurality of rod-shaped resonating arms; and a base portion that connects one set of end portions of the respective resonating arms, wherein a plurality of slits is formed on the other set of end portions of the resonating arms.

A tuning-fork type piezoelectric resonating device is formed using a piezoelectric substrate in which a weight portion having a larger width than the width of each of resonating arms is formed in each of the end portions of a pair of resonating arms, and a plurality of frequency adjustment slits is formed in each of the weight portions. Since the frequency adjustment slits are formed in the weight portion having a large width, even if etching time exceeds a desired etching time, that is, over-etching occurs, when forming the outer shape of the piezoelectric substrate by etching processing using photolithography technique, a decrease in the resonance frequency of tuning-fork vibration due to a decrease in the width of the respective resonating arms is canceled by an increase in the resonance frequency due to an increase in the width of the frequency adjustment slits. Thus, it is possible to greatly decrease the deviation from a predetermined frequency due to over-etching. Even if the etching time is deficient, an increase in the resonance frequency of tuning-fork vibration due to the width of the respective resonating arms larger than a designed value is canceled by a decrease in the resonance frequency due to the width of the frequency adjustment slits smaller than a designed value. Thus, it is posible to greatly decrease the deviation from a predetermined frequency due to deficient etching time. In addition, it is possible to miniaturize the piezoelectric resonating device by forming the weight portions.

### Application Example 2

This application example of the invention is directed to the piezoelectric resonating device of the above application example, wherein the respective slits have the same longitudinal dimension, and the positions of both end portions in the longitudinal direction are identical to each other.

Frequency adjustment slits which have the same width dimension and the same longitudinal dimension and of which the positions of both end portions in the longitudinal direction are identical to each other are formed in the weight portions having a large width. Thus, it is possible to greatly decrease the deviation from a predetermined frequency due to over-etching when forming the shape of the piezoelectric substrate by an etching method. Moreover, it becomes easy to manufacture a photomask pattern of the frequency adjustment slits.

### Application Example 3

This application example of the invention is directed to the piezoelectric resonating device of the above application example, wherein the respective slits have the same longitudinal dimension, and the positions of both end portions in the longitudinal direction are alternatively shifted from each other.

Frequency adjustment slits which have the same width dimension and the same longitudinal dimension and of which the positions of both end portions in the longitudinal direction are alternatively shifted from each other are formed in the weight portions having a large width. Thus, it is possible to finely control the inertia of the weight portions when the resonating arms perform flexural vibration and to finely adjust the frequency of the tuning-fork type piezoelectric resonating device. Furthermore, by forming such frequency adjustment slits, it is possible to greatly decrease the deviation from a predetermined frequency due to over-etching when forming the shape of the piezoelectric substrate by an etching method.

### Application Example 4

This application example of the invention is directed to the piezoelectric resonating device of the above application example, wherein the respective slits have the same longitudinal dimension, and the width dimensions thereof are different from each other.

Frequency adjustment slits which have the same width dimension and the same longitudinal dimension and of which the width dimensions thereof are different from each other are formed in the weight portions having a large width. Thus, it is possible to finely control the inertia of the weight portions when the resonating arms perform flexural vibration and to finely adjust the frequency of the tuning-fork type piezoelectric resonating device. Furthermore, by forming such frequency adjustment slits, it is possible to greatly decrease the deviation from a predetermined frequency due to over-etching when forming the shape of the piezoelectric substrate by an etching method.

### Application Example 5

This application example of the invention is directed to the piezoelectric resonating device of the above application example, wherein the respective slits include a plurality of sets of slits in which one set of end portions in the longitudinal direction of two adjacent slits are connected by a connecting slit.

Bracket-shaped frequency adjustment slits which have the same width dimension and the same longitudinal dimension and of which the positions of both end portions in the longitudinal direction are identical to each other, and in which one set of end portions in the longitudinal direction of two adjacent slits are connected to each other are formed in the weight portions having a large width. Thus, it is possible to finely control the inertia of the weight portions when the resonating arms perform flexural vibration and to finely adjust the frequency of the tuning-fork type piezoelectric resonating device. Furthermore, by forming such frequency adjustment slits, it is possible to greatly decrease the deviation from a predetermined frequency due to over-etching when forming the shape of the piezoelectric substrate by an etching method.

### Application Example 6

This application example of the invention is directed to the piezoelectric resonating device of the above application example, wherein one set of end portions of the respective slits is open to an end of the weight portion.

Frequency adjustment slits in which one set of end portions of the respective slits are open to an end of the weight portion are formed in the weight portions having a large width. Thus, it is possible to finely control the inertia of the weight portions when the resonating arms perform flexural vibration and to finely adjust the frequency of the tuning-fork type piezoelectric resonating device. Furthermore, by forming such frequency adjustment slits, it is possible to greatly decrease the deviation from a predetermined frequency due to over-etching when forming the shape of the piezoelectric substrate by an etching method.

### Application Example 7

This application example of the invention is directed to the piezoelectric resonating device of any of Application Examples 1 to 6, wherein the respective slits are formed so as to be symmetrical to a center line of vibration of the piezoelectric substrate.

Frequency adjustment slits which are formed so as to be symmetrical to a center line of vibration of the piezoelectric substrate are formed in the weight portions having a large width. Thus, it is possible to improve the balance of the weight portions, suppress unnecessary spurious vibration occurring in the tuning-fork type piezoelectric resonating device, and improve frequency stability. Furthermore, it is possible to greatly decrease the deviation from a predetermined frequency due to over-etching when forming the shape of the piezoelectric substrate by an etching method.

### Application Example 8

This application example of the invention is directed to a piezoelectric resonating device including: a piezoelectric substrate which includes a plurality of rod-shaped resonating arms, a base portion that connects one set of end portions of the respective resonating arms, and groove portions formed on each of a front surface and a rear surface along the center line of vibration of each of the resonating arms; and excitation electrodes which are formed on the front and rear surfaces of each of the resonating arms including at least the inner surfaces of the respective groove portions and which electrically connect electrode pads formed on the base portion, in which a plurality of frequency adjustment slits penetrating through the front and rear surfaces of the resonating arms so as to extend in a straight line form along the longitudinal direction of the respective resonating arms are formed on the other set of end portions of the resonating arms.

Frequency adjustment slits penetrating through the front and rear surfaces of the resonating arms so as to extend in a straight line form along the longitudinal direction of the respective resonating arms are formed on the end portions of the resonating arms. Thus, it is possible to greatly decrease the deviation from a predetermined frequency due to over-etching when forming the shape of the piezoelectric substrate by an etching method. Furthermore, it is possible to miniaturize the tuning-fork type piezoelectric resonating device.

### Application Example 9

This application example of the invention is directed to a piezoelectric resonating device including: a piezoelectric substrate which includes a plurality of rod-shaped resonating arms, a base portion that connects connects one set of end portions of the respective resonating arms, weight portions which are formed on the other set of end portions of the respective resonating arms and which have a larger width than the width of the respective resonating arms, and groove portions formed on each of a front surface and a rear surface along the center line of vibration of each of the resonating arms; and excitation electrodes which are formed on the front and rear surfaces and both side surfaces of each of the resonating arms including at least the inner surfaces of the respective groove portions, in which a plurality of frequency adjustment slits penetrating through the front and rear surfaces of the weight portions so as to extend in a straight line form along the longitudinal direction of the respective resonating arms are formed in each of the respective weight portions, voltages of different signs are applied to the facing excitation electrodes on the front and rear surfaces, the excitation electrodes on both side surfaces are divided into two parts to which voltages having a sign different from those applied to the excitation electrodes on the facing front and rear surfaces are applied.

Frequency adjustment slits are formed in the weight portions having a large width, of the respective resonating arms, and the excitation electrodes are arranged on the front and rear surfaces and both side surfaces of the respective resonating arms. Due to the frequency adjustment slits, even if etching time exceeds a desired etching time, that is, over-etching occurs, when forming the shape of the piezoelectric substrate by etching processing, a decrease in the resonance frequency of torsional vibration due to a decrease in the width of the respective resonating arms is canceled by an increase in the resonance frequency due to an increase in the width of the frequency adjustment slits. Thus, it is possible to greatly decrease the deviation from a predetermined frequency due to over-etching. Furthermore, by forming the weight portions, it is possible to miniaturize the piezoelectric resonator.

### Application Example 10

This application example of the invention is directed to a resonating gyro device including: a base portion; a pair of detection resonating arms formed on the same straight line so as to protrude from two facing ends of the base portion; a pair of connecting arms formed on the same straight line so as to protrude from another two facing ends of the base portion in a direction orthogonal to the detection resonating arms, respectively; a pair of driving resonating arms protruding from the distal end portions of the respective connecting arms in both directions orthogonal to the connecting arms, respectively; and excitation electrodes which are formed on at least the pair of detection resonating arms and the pair of driving resonating arms and which connect a plurality of electrode pads formed on the base portion, in which the respective detection resonating arms and the respective driving resonating arms have weight portions which are formed in distal end portions thereof and which have a width larger than the width of the detection resonating arms and the driving resonating arms, and a plurality of frequency adjustment slits is formed in the weight portions.

Weight portions having a larger width than the width of the detection resonating arms and the driving resonating arms are formed in the distal end portions of the detection resonating arms and the driving resonating arms, and frequency adjustment slits are formed in the weight portions. Since the respective resonating arms are excited by flexural vibration, it is possible to greatly decrease the deviation from a predetermined frequency due to over-etching when forming the shape of the piezoelectric substrate by an etching method.

### Application Example 11

This application example of the invention is directed to a method of manufacturing the piezoelectric resonating device according to any of Application Examples 1 to 9, including forming the outer shape of the piezoelectric resonating device and the frequency adjustment slits by etching; forming the groove portions by etching; and forming the excitation electrodes.

By using the manufacturing method, it is possible to greatly decrease the deviation from a predetermined frequency due to over-etching when forming the shape of a piezoelectric substrate for a tuning-fork type piezoelectric resonating device by etching.

### Application Example 12

This application example of the invention is directed to a method of manufacturing the resonating gyro device according to Application Example 10, including forming the outer shape (shape such as an outline) of the resonating gyro device and the frequency adjustment slits by etching; and forming the excitation electrodes.

By using the manufacturing method, it is possible to greatly decrease the deviation from a predetermined frequency due to over-etching when forming the shape of a piezoelectric substrate for a resonating gyro device by etching.

### Application Example 13

This application example of the invention is directed to a piezoelectric resonator including the piezoelectric resonating device of any of Application Examples 1 to 9 and a package in which the piezoelectric resonating device is accommodated.

The piezoelectric resonator includes a piezoelectric resonating device which includes a piezoelectric substrate including a base portion, a plurality of rod-shaped resonating arm, weight portions having a large width, formed in the respective resonating arms, frequency adjustment slits formed in the respective weight portions, and groove portions formed on the front and rear surfaces of each of the resonating arms, and excitation electrodes arranged on the front and rear surfaces of each of the resonating arms, and a package in which the piezoelectric resonating device is accommodated.

Since the frequency adjustment slits are formed in the weight portion having a large width, even if etching time exceeds a desired etching time, that is, over-etching occurs, when forming the shape of the piezoelectric substrate by etching, a decrease in the resonance frequency of tuning-fork vibration due to a decrease in the width of the respective resonating arms is canceled by an increase in the resonance frequency due to an increase in the width of the frequency adjustment slits. Thus, it is possible to greatly decrease the deviation from a predetermined frequency due to over-etching. Furthermore, by forming the weight portions, it is possible to miniaturize the piezoelectric resonator.

### Application Example 14

This application example of the invention is directed to a resonating gyro sensor including the resonating gyro device of Application Example 10 and a package in which the resonating gyro device is accommodated.

The resonating gyro sensor includes a resonating gyro device including a base portion, a pair of detection resonating arms, a pair of connecting arms, a pair of driving resonating arms, weight portions having a large width provided in each of the distal end portions of the detection resonating arms and the driving resonating arms, and frequency adjustment slits formed in the weight portions, and a package in which the resonating gyro device is accommodated.

Since the respective resonating arms are excited by flexural vibration, by forming the frequency adjustment slits, it is possible to greatly decrease the deviation from a predetermined frequency due to over-etching when forming the shape of the piezoelectric substrate by an etching method.

### Application Example 15

This application example of the invention is directed to a piezoelectric oscillator including the piezoelectric resonating device of any of Application Examples 1 to 9; an IC component that excites the piezoelectric resonating device; and a package in which the piezoelectric resonating device is air-tightly sealed, and the IC component is accommodated.

The piezoelectric oscillator includes the piezoelectric resonating device, the IC component that excites the piezoelectric resonating device, and the package in which the piezoelectric resonating device and the IC component are accommodated. With this configuration, it is possible to obtain a piezoelectric oscillator which has a small size and little unnecessary vibration, and in which a frequency adjustment amount of the piezoelectric resonating device is small.

### Application Example 16

This application example of the invention is directed to a resonating gyro apparatus including the resonating gyro device of Application Example 10; an IC component that excites the driving resonating arms of the resonating gyro device and detects and processes the frequency of the detection resonating arms; and a package in which the resonating gyro device is air-tightly sealed, and the IC component is accommodated.

The resonating gyro apparatus includes the resonating gyro device, the IC component that excites the driving resonating arms of the resonating gyro device and detects and processes the detection resonating arms, and the package in which the resonating gyro device and the IC component are accommodated. Since the respective resonating arms are excited by flexural vibration, it is possible to greatly decrease the deviation from a predetermined frequency due to over-etching when forming the shape of the piezoelectric substrate by an etching method. Moreover, since the frequency adjustment slit are provided, it is possible to obtain a resonating gyro apparatus in which the frequency adjustment amount of the resonating gyro device is small, and which has a small size and little unnecessary vibration.

### BRIEF DESCRIPTION OF THE DRAWINGS

The invention will be described with reference to the accompanying drawings, wherein like numbers reference like elements.

FIGS. 1A and 1B are views showing a simplified configuration of a piezoelectric resonating device according to an embodiment of the invention, in which FIG. 1A is a plan view, and FIG. 1B is a cross-sectional view.

FIG. 2 is a view illustrating qualitatively the operation of the piezoelectric resonating device according to the embodiment of the invention.

FIG. 3 is a view obtained through simulation, of the relationship between the number of slits and a frequency variation amount.

FIGS. 4A to 4D are plan views of a modified example of a frequency adjustment slit formed in a weight portion.

FIGS. 5A and 5B are views showing a simplified configuration of a piezoelectric resonating device according to a second embodiment of the invention, in which FIG. 5A is a plan view, and FIG. 5B is a cross-sectional view.

FIGS. 6A and 6B are views showing a simplified configuration of a piezoelectric resonating device (torsional resonating device) according to a third embodiment of the invention.

FIGS. 7A and 7B are view showing a simplified configuration of a piezoelectric resonating device (resonating gyro device) according to a fourth embodiment of the invention, in which FIG. 7A is a plan view, and FIG. 7B is a view illustrating the operation thereof.

FIG. 8 is a flowchart of a step of forming the outer shape of a piezoelectric substrate.

FIG. 9 is a flowchart of a step of forming a groove portion of the piezoelectric substrate.

FIG. 10 is a flowchart of an electrode forming step.

FIG. 11 is a cross-sectional view showing the configuration of a piezoelectric resonator.

FIG. 12 is a cross-sectional view showing the configuration of a piezoelectric oscillator.

FIG. 13 is a plan view showing the configuration of a tuning-fork type piezoelectric resonating device according to the related art.

FIG. 14 is a plan view showing the configuration of a weight portion of the tuning-fork type piezoelectric resonating device according to the related art.

FIG. 15 is a plan view showing the configuration of a resonating gyro device according to the related art.

### DESCRIPTION OF EXEMPLARY EMBODIMENTS

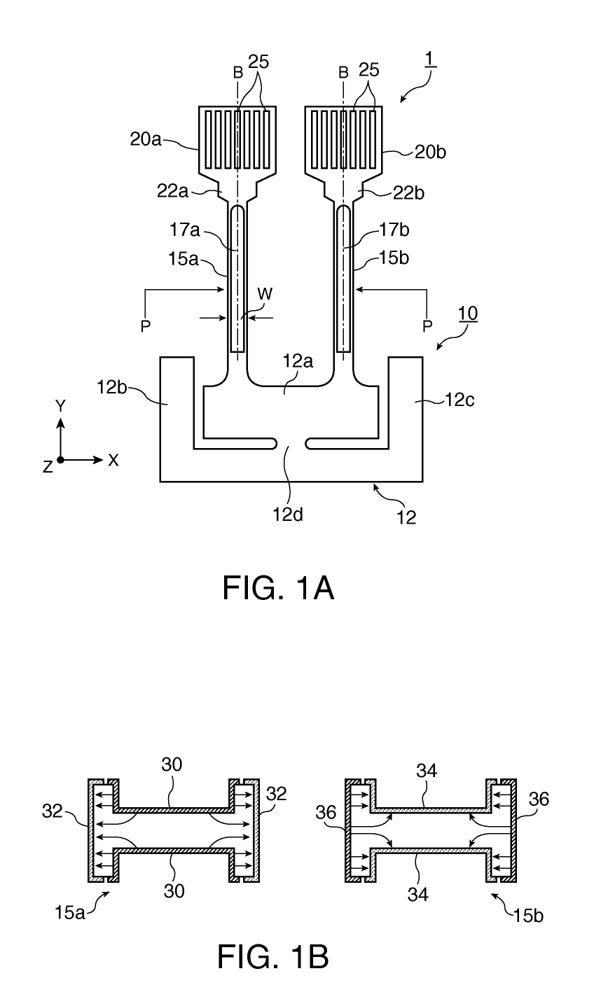

Hereinafter, embodiments of the invention will be described in detail with reference to the drawings. FIGS. 1A and 1B are views showing a simplified configuration of a piezoelectric resonating device 1 according to an embodiment of the invention, in which FIG. 1A is a plan view, and FIG. 1B is a cross-sectional view taken along the line P-P.

The piezoelectric resonating device (tuning-fork type quartz crystal resonating device) 1 mainly includes a piezoelectric substrate 10 and excitation electrodes 30, 32, 34, and 36.

The piezoelectric substrate 10 includes a plurality of rod-shaped resonating arms 15a and 15b disposed in parallel and separated from each other, a base portion 12 that connects one set of end portions of the resonating arms 15a and 15b, and weight portions 20a and 20b which are continuous to the other set of end portions of the resonating arms 15a and 15b and which have a width larger than the width of the resonating arms 15a and 15b. The piezoelectric substrate 10 also includes groove portions 17a and 17b which are formed on each of a front surface and a rear surface along the center line of vibration B of each of the resonating arms 15a and 15b. A plurality of frequency adjustment slits 25 penetrating through the front and rear surfaces of each of the weight portions 20a and 20b so as to extend in a straight line form along the longitudinal direction of the respective resonating arms 15a and 15b are formed on the respective weight portions 20a and 20b.

The piezoelectric resonating device 1 includes excitation electrodes 30, 32, 34, and 36 which are formed on the front and rear surfaces of the resonating arms 15a and 15b including at least the groove portions 17a and 17b of the piezoelectric substrate 10 and the side surfaces of the groove portions 17a and 17b and both side surfaces of the resonating arms 15a and 15b and which electrically connect a plurality of electrode pads (not shown) formed on the base portion 12.

The base portion 12 includes a base body 12a having an approximately rectangular shape and an L-shaped supporting portion 12b and an inverted L-shaped supporting portion 12c which are connected to the base body 12a through the center (connecting portion 12d) of the other end of the base body 12a, and a connecting portion 12d. The base end portion of the L-shaped supporting portion 12b is connected to the base end portion of the inverted L-shaped supporting portion 12c. This connected portion is connected to the center of one end of the base body 12a through the connecting portion 12d. The end portions of the resonating arms 15a and 15b are connected to the other end of the base body 12a.

The resonating arms 15a and 15b protrude in parallel from one end of the base body 12a with a predetermined gap therebetween. The weight portions 20a and 20b having a larger width than the width of the resonating arms 15a and 15b are connected to the distal end portions of the resonating arms 15a and 15b, respectively. The plurality of slits 25 are formed in the weight portions 20a and 20b so as to penetrate through the front and rear surfaces thereof. The slits 25 extend in parallel to the respective resonating arms 15a and 15b and are disposed to be symmetrical about the center line of vibration B that passes the center of each of the resonating arms 15a and 15b.

The groove portions 17a and 17b are formed on the front and rear surfaces of the resonating arms 15a and 15b so as to be symmetrical about the respective center lines of vibration B and extend along the longitudinal direction of the resonating arms 15a and 15b. That is, the resonating arms 15a and 15b and the weight portions 20a and 20b including the slits 25 are formed in the same shape and are formed to be symmetrical about the center line that passes the center of the piezoelectric substrate 10 so that tuning-fork vibration is excited stably.

FIG. 1B is a cross-sectional view showing the arrangement of the excitation electrodes 30, 32, 34, and 36 formed on each of the resonating arms 15a and 15b. The excitation electrodes 30 and 34 are formed on the front and rear surfaces of the groove portions 17a and 17b and the side surfaces of the groove portions 17a and 17b. The excitation electrodes 32 and 36 are formed on both side surfaces of each of the resonating arms 15a and 15b.

Voltages of different signs are applied to the excitation electrodes 30 and 36 and the excitation electrodes 32 and 43 through the plurality of electrode pads formed on the base portion 12. That is, when a positive (+) voltage is applied to the excitation electrodes 30 and 36, a negative (−) voltage is applied to the excitation electrodes 32 and 34. As a result, an electric field as indicated by arrows in FIG. 1B is generated, and tuning-fork vibration that is symmetrical about the center line passing the center of the piezoelectric resonating device 1 is excited. Since the groove portions 17a and 17b are formed, it is possible to strengthen the electric field intensity and excite tuning-fork type more efficiently. That is, it is possible to decrease the CI (Crystal Impedance) of the piezoelectric resonating device 1.

Moreover, in the embodiment of FIGS. 1A and 1B, although the base portion 12 has been described to include the base body 12a, the L-shaped supporting portion 12b, the inverted L-shaped supporting portion 12c, and the connecting portion 12d, the base portion 12 may include only the base body 12a.

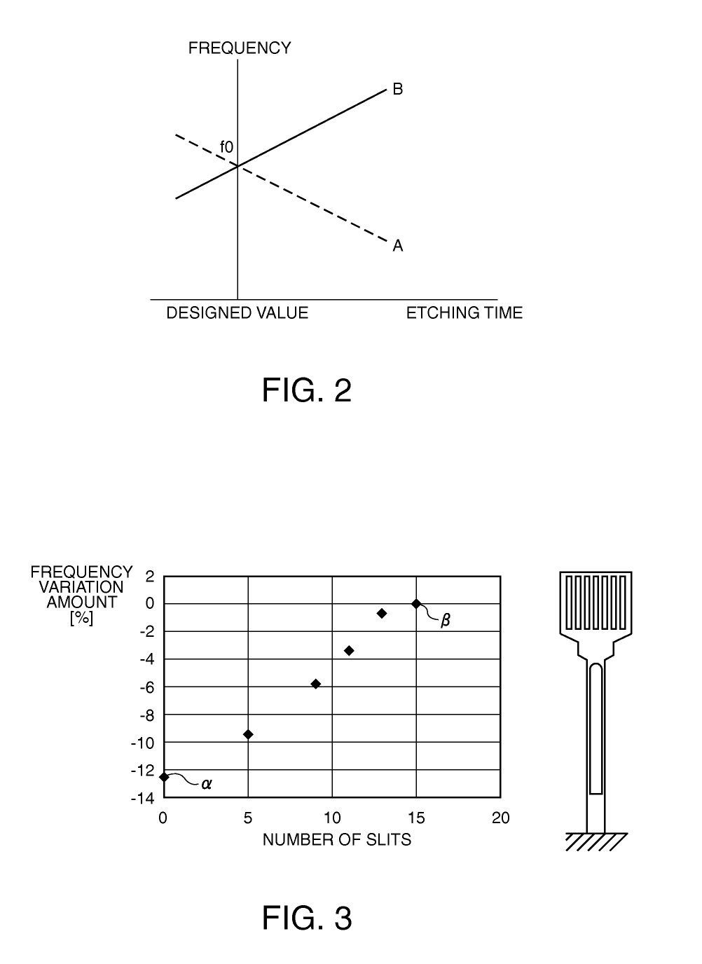

FIG. 2 is a view showing quantitatively the relationship between etching time and resonance frequency when excitation electrodes are formed on the tuning-fork type piezoelectric substrate 10 according to the invention and the resonance frequency is measured. The designed value on the etching time axis represents a designed value of etching time. Under the designed etching time, the frequency of the tuning-fork type piezoelectric substrate 10 becomes a predetermined frequency f0. When the etching time exceeds the designed etching time (when over-etching occurs), the width w of the resonating arms 15a and 15b decreases. As a result, the resonance frequency becomes smaller than the predetermined frequency f0 as shown in the curve (broken line) A in FIG. 2. On the other hand, as in the case of the piezoelectric resonating device 1 shown in FIGS. 1A and 1B, when the plurality of slits 25 are formed in the weight portions 20a and 20b, the frequency of the tuning-fork type piezoelectric resonating device 1 increases as shown in the curve (solid line) B since the weight of the weight portions 20a and 20b decreases due to over-etching. That is, by forming the plurality of slits 25 in the weight portions 20a and 20b as in the case of the invention, it is expected that the deviation of frequency from the predetermined frequency f0 due to unevenness in etching time (including unevenness in concentration of etching solution and unevenness in temperature etching solution) of is decreased greatly.

The left drawing of FIG. 3 illustrates the relationship between the number of slits and a frequency variation amount, in which the number of frequency adjustment slits is on the horizontal axis, the resonance frequency variation amount (%) of a flexural piezoelectric resonator is on the vertical axis. The frequency variation amount (%) is a percentage of Δf/f0 in which f0 is the designed resonance frequency of a flexural piezoelectric resonator, and Δf is a frequency variation from the designed resonance frequency.

The flexural piezoelectric resonator used in the simulation is a flexural piezoelectric resonator in which a weight portion including frequency adjustment slit and a resonating arm are connected as shown on the right of FIG. 3. The flexural piezoelectric resonator has a length of 1.37 mm, the resonating arm has a thickness of 100 μm, a groove portion having a thickness of 45 μm is formed on the front and rear surfaces of the resonating arm, and the end portions of the resonating arm are fixed. As an over-etching amount, the width (in the X-axis direction) of the entire resonating arm including the weight portion was decreased by 4 μm from a designed value.

Since the width of the resonating arm is decreased (over-etched) by 4 μm from the designed value, when no frequency adjustment slit is provided, the resonance frequency of the flexural piezoelectric resonator is lower than f0, and a variation amount indicated by point α is obtained.

Subsequently, when a frequency adjustment slit is formed in the weight portion, the weight of the weight portion decreases, and the frequency of the flexural piezoelectric resonator increases. The diamond marks in FIG. 3 are the frequency variation amounts of the flexural piezoelectric resonator when the number of frequency adjustment slits is increased to 5, 9, 11, 13, and 15. As a computation example, when the number of frequency adjustment slits is increased to 15, a frequency variation amount indicated by point β is obtained. In this case, a decrease in frequency due to over-etching of the width of the resonating arm, namely a decrease of the width by 4 μm is canceled by an increased in frequency due to 15 frequency adjustment slits. As a result, the frequency variation amount approaches zero.

A tuning-fork type piezoelectric resonating device is formed using a piezoelectric substrate in which a weight portion having a larger width than the width of each of resonating arms is formed in each of the end portions of a pair of resonating arms, and a plurality of frequency adjustment slits is formed in each of the weight portions. Since the frequency adjustment slits are formed in the weight portion having a large width, even if etching time exceeds a desired etching time, that is, over-etching occurs, when forming the outer shape of the piezoelectric substrate by etching processing using photolithography technique, a decrease in the resonance frequency of tuning-fork vibration due to a decrease in the width of the respective resonating arms is canceled by an increase in the resonance frequency due to an increase in the width of the frequency adjustment slits. Thus, it is possible to greatly decrease the deviation from a predetermined frequency due to over-etching. Conversely, even if the etching time is deficient, an increase in the resonance frequency of tuning-fork vibration due to the width of the respective resonating arms larger than a designed value is canceled by a decrease in the resonance frequency due to the width of the frequency adjustment slits smaller than a designed value. Thus, it is posible to greatly decrease the deviation from a predetermined frequency due to deficient etching time.

In addition, although it is possible to miniaturize the piezoelectric resonating device by forming the weight portions, the groove portions 17a and 17b may not be formed on both front and rear surfaces of the resonating arms 15a and 15b.

The piezoelectric resonating device shown in FIG. 1A is an example in which the respective frequency adjustment slits 25 formed in the weight portions 20a and 20b have the same width dimension and the same longitudinal dimension, and the positions of both end portions in the longitudinal direction are identical to each other.

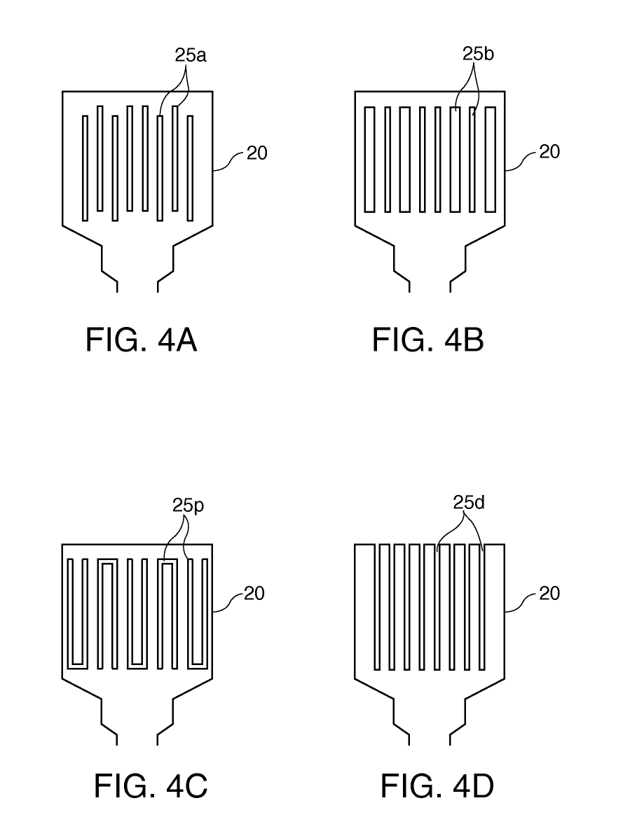

FIGS. 4A to 4D show modified examples of the frequency adjustment slit 25. FIG. 4A shows an example in which the respective frequency adjustment slits 25 have the same width dimension and the same longitudinal dimension, and the positions of both end portions in the longitudinal direction are alternatively shifted from each other.

FIG. 4B shows an example in which the respective frequency adjustment slits 25b have the same longitudinal dimension and different width dimensions.

When frequency adjustment slits which have the same width dimension and the same longitudinal dimension and of which the positions of both end portions in the longitudinal direction are identical to each other are formed in the weight portions having a large width as shown in FIG. 1A, it is possible to greatly decrease the deviation from a predetermined frequency due to over-etching when forming the shape (outer shape or outline) of the piezoelectric substrate by an etching method. Moreover, it becomes easy to manufacture a photomask pattern of the frequency adjustment slits.

Moreover, when frequency adjustment slits which have the same width dimension and the same longitudinal dimension and of which the positions of both end portions in the longitudinal direction are alternatively shifted from each other are formed in the weight portions having a large width as shown in FIG. 4A, it is possible to finely control the inertia of the weight portions when the resonating arms perform flexural vibration and to finely adjust the frequency of the tuning-fork type piezoelectric resonating device. Furthermore, by forming such frequency adjustment slits, it is possible to greatly decrease the deviation from a predetermined frequency due to over-etching when forming the shape of the piezoelectric substrate by an etching method.

Moreover, when frequency adjustment slits which have the same longitudinal dimension and of which the width dimensions thereof are different from each other are formed in the weight portions having a large width as shown in FIG. 4B, it is possible to finely control the inertia of the weight portions when the resonating arms perform flexural vibration and to finely adjust the frequency of the tuning-fork type piezoelectric resonating device. Furthermore, by forming such frequency adjustment slits, it is possible to greatly decrease the deviation from a predetermined frequency due to over-etching when forming the shape of the piezoelectric substrate by an etching method.

FIG. 4C shows an example in which the respective frequency adjustment slits 25 include a plurality of sets of bracket-shaped frequency adjustment slits 25p which have the same width dimension and the same longitudinal dimension and of which the positions of both end portions in the longitudinal direction are identical to each other, and in which one set of end portions in the longitudinal direction of two adjacent slits are connected to each other. The positions of the connecting slits of the adjacent frequency adjustment slits 25p are alternately reversed.

FIG. 4D shows an example in which one set of end portions of respective frequency adjustment slits 25d are open to an end of the weight portion.

Moreover, the slits 25a to 25p shown in FIGS. 4A to 4D may be used in appropriate combinations, and the frequency adjustment slit may be formed in two or three stages. Furthermore, the frequency adjustment slits may be slits which do not penetrate through the front and rear surfaces but may alternately formed on the front and rear surfaces.

When the bracket-shaped frequency adjustment slits which have the same width dimension and the same longitudinal dimension and of which the positions of both end portions in the longitudinal direction are identical to each other, and in which one set of end portions in the longitudinal direction of two adjacent slits are connected to each other are formed in the weight portions having a large width as shown in FIG. 4C, it is possible to finely control the inertia of the weight portions when the resonating arms perform flexural vibration and to finely adjust the frequency of the tuning-fork type piezoelectric resonating device. Furthermore, by forming such frequency adjustment slits, it is possible to greatly decrease the deviation from a predetermined frequency due to over-etching when forming the shape of the piezoelectric substrate by an etching method.

Moreover, when the frequency adjustment slits in which one set of end portions of the respective slits are open to an end of the weight portion are formed in the weight portions having a large width as shown in FIG. 4D, it is possible to finely control the inertia of the weight portions when the resonating arms perform flexural vibration and to finely adjust the frequency of the tuning-fork type piezoelectric resonating device. Furthermore, by forming such frequency adjustment slits, it is possible to greatly decrease the deviation from a predetermined frequency due to over-etching when forming the shape of the piezoelectric substrate by an etching method.

The frequency adjustment slits 25 formed in the piezoelectric resonating device (tuning-fork type quartz crystal resonating device) 1 are preferably formed so as to be symmetrical to the center lines of vibration B of the respective resonating arms 15a and 15b. By doing so, it is possible to improve the balance when the resonating arms 15a and 15b are excited by flexural vibration, and to secure stable vibration.

When frequency adjustment slits which are formed so as to be symmetrical to a center line of vibration B of the piezoelectric substrate are formed in the weight portions having a large width, it is possible to improve the balance of the weight portions, suppress unnecessary spurious vibration occurring in the tuning-fork type piezoelectric resonating device, and improve frequency stability. Furthermore, it is possible to greatly decrease the deviation from a predetermined frequency due to over-etching when forming the shape of the piezoelectric substrate by an etching method.

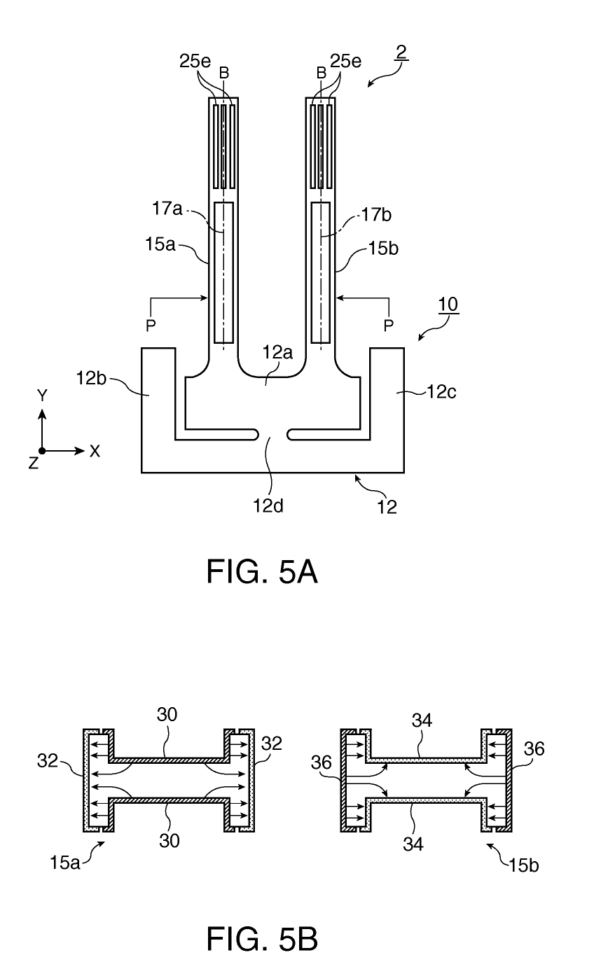

FIGS. 5A and 5B are views showing the configuration of a piezoelectric resonating device (tuning-fork type quartz crystal resonating device) 2 according to the second embodiment, in which FIG. 5A is a plan view, and FIG. 5B is across-sectional view taken along the P-P line. A piezoelectric substrate 10 of the piezoelectric resonating device 2 includes a plurality of rod-shaped resonating arms 15a and 15b disposed in parallel and separated from each other, a base portion 12 that connects one set of end portions of the resonating arms 15a and 15b, groove portions 17a and 17b which are formed on each of a front surface and a rear surface along the center line of vibration B of each of the resonating arms 15a and 15b. Moreover, a plurality of frequency adjustment slits 25e penetrating through the front and rear surfaces of each of the resonating arms 15a and 15b so as to extend in a straight line form along the longitudinal direction of the resonating arms 15a and 15b are formed on the other set of end portions of the resonating arms 15a and 15b. The frequency adjustment slits 25e are formed to be symmetrical about the center lines of vibration B of the resonating arms 15a and 15b.

Moreover, excitation electrodes 30 and 32 and 34 and 36 are formed on the front and rear surfaces of each of the resonating arms 15a and 15b including at least the side surfaces of each of the groove portions 17a and 17b and the side surfaces of the groove portions 17a and 17b and both side surfaces of each of the resonating arms 15a and 15b as shown in the cross-sectional view of FIG. 5B. In addition, lead electrodes (not shown) are formed so as to electrically connect electrode pads (not shown) formed on the base portion 12.

Similarly to the piezoelectric resonating device 1 shown in FIGS. 1A and 1B, the base portion 12 includes a rectangular base body 12a, an L-shaped supporting portion 12b, an inverted L-shaped supporting portion 12c, and a connecting portion 12d. The end portion of the L-shaped supporting portion 12b is connected to the end portion of the inverted L-shaped supporting portion 12c. This connected portion is connected to one end of the base body 12a through the connecting portion 12d. The end portions of the resonating arms 15a and 15b are connected to the other end of the base body 12a.

The supporting portions 12b and 12c may not be provided, and the base portion 12 may include only the base body 12a.

When frequency adjustment slits penetrating through the front and rear surfaces of the resonating arms so as to extend in a straight line form along the longitudinal direction of the respective resonating arms are formed on the end portions of the resonating arms, it is possible to greatly decrease the deviation from a predetermined frequency due to over-etching when forming the shape of the piezoelectric substrate by an etching method. Furthermore, it is possible to miniaturize the tuning-fork type piezoelectric resonating device.

The shapes and the arrangement patterns of the frequency adjustment slits shown in FIGS. 4A to 4D can be applied to this example.

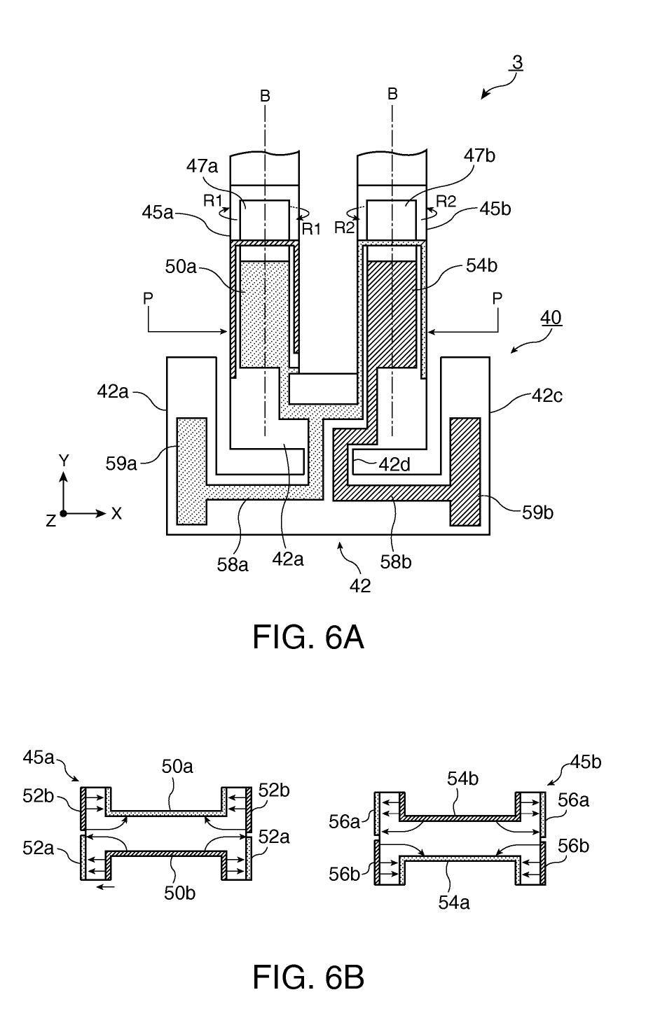

FIGS. 6A and 6B are views showing the configuration of a piezoelectric resonating device (torsional quartz crystal resonating device) 3 according to the third embodiment, in which FIG. 6A is a plan view of a main part excluding weight portions, and FIG. 6B is a cross-sectional view taken along the line P-P. The weight portions of the piezoelectric resonating device (torsional quartz crystal resonating device) 3 have the same structure as the weight portions 20a and 20b shown in FIGS. 1A and 1B and the weight portions 20 shown in FIGS. 4A to 4D, and redundant description thereof will not be provided.

A quartz crystal substrate 40 of the torsional quartz crystal resonating device 3 includes a plurality of rod-shaped resonating arms 45a and 45b, a base portion 42 that connects one set of end portions of the resonating arms 45a and 45b, weight portions (the same as the weight portions shown in FIG. 1A or FIGS. 4A to 4D) which are formed on the other set of end portions of each of the resonating arms 45a and 45b and which have a larger width than the width of the resonating arms 45a and 45b, and groove portions 47a and 47b formed on the front and rear surfaces along the center lines of vibration B of the resonating arms 45a and 45b. Furthermore, a plurality of frequency adjustment slits penetrating through the front and rear surfaces of each of the weight portions formed in the distal end portions of the resonating arms 45a and 45b so as to extend in a straight line form along the longitudinal direction of the resonating arms 45a and 45b are formed in the weight portions.

Excitation electrodes 50a and 50b and 54a and 54b are formed on the front and rear surfaces of the resonating arms 45a and 45b including the inner surfaces and the side surfaces of the groove portions 47a and 47b, respectively. Furthermore, the excitation electrodes on both side surfaces of the resonating arms 45a and 45b are divided into two parts in the vertical direction of the drawing as shown in FIG. 6B, and excitation electrodes 52a and 52b and 56a and 56b are formed on the resonating arms 45a and 45b, respectively. Voltages of different signs are applied to the excitation electrodes 50a and 50b on the front and rear surfaces of the resonating arm 45a. Voltages of different signs are applied to the excitation electrodes 54a and 54b on the front and rear surfaces of the resonating arm 45b. Voltages of different signs are applied to the excitation electrodes 50a and 54b (50b and 54a).

Furthermore, voltages of signs different from those applied to the excitation electrodes 50a and 50b (54a and 54b) on the facing front and rear surfaces are applied to the excitation electrodes 52b and 52a (56a and 56b) on both side surfaces.

That is, voltages of different signs are applied to the excitation electrode 50a on the front surface of the resonating arm 45a and the upper excitation electrodes 52b in the drawing, of both side surfaces, and voltages of different signs are applied to the excitation electrode 50b on the rear surface and the lower excitation electrodes 52a in the drawing, of both side surfaces. Similarly, voltages of different signs are applied to the excitation electrode 54b on the front surface of the resonating arm 45b and the upper excitation electrodes 56a in the drawing, of both side surfaces, and voltages of different signs are applied to the excitation electrode 54a on the rear surface and the lower excitation electrodes 56b in the drawing, of both side surfaces. As a result, electric field as indicated by arrows in FIG. 6B is generated, and torsional vibration is excited in an opposite direction as indicated by arrows R1 and R2 in FIG. 6A.

The slits formed in the weight portions of the torsional quartz crystal resonating device 3 may be formed to be symmetrical about the center lines of vibration B from both outer sides of the weight portions, which is preferable from the perspective of efficiency. This is because in the case of torsional vibration, mass at a position distant from the center line of vibration B has more contribution to the resonance frequency. That is, when removing the same mass, removal of mass at a position distant from the center line of vibration B results in a more variation in frequency than removing of mass at a position close to the center line of vibration B.

Frequency adjustment slits are formed in the weight portions having a large width, of the respective resonating arms, and the excitation electrodes are arranged on the front and rear surfaces and both side surfaces of the respective resonating arms. Due to the frequency adjustment slits, even if etching time exceeds a desired etching time, that is, over-etching occurs, when forming the shape of the piezoelectric substrate by etching processing, a decrease in the resonance frequency of torsional vibration due to a decrease in the width of the respective resonating arms is canceled by an increase in the resonance frequency due to an increase in the width of the frequency adjustment slits. Thus, it is possible to greatly decrease the deviation from a predetermined frequency due to over-etching. Furthermore, by forming the weight portions, it is possible to miniaturize the piezoelectric resonator.

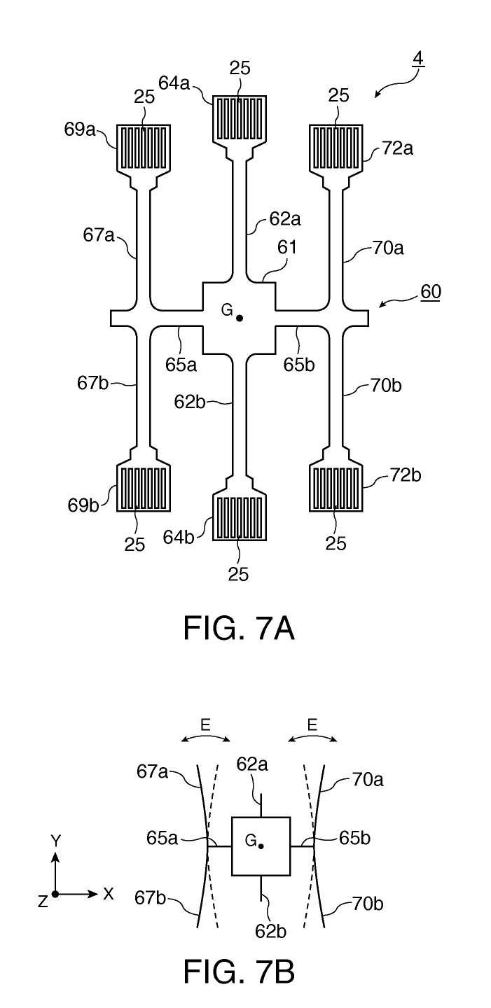

FIGS. 7A and 7B are plan views showing the configuration of a resonating gyro device 4 according to the fourth embodiment. A piezoelectric substrate 60 of the resonating gyro device 4 includes an approximately rectangular base portion 61, a pair of detection resonating arms 62a and 62b formed on the same straight line so as to protrude from the centers of two facing ends of the base portion 61; a pair of connecting arms 65a and 65b formed on the same straight line so as to protrude from the centers of another two facing ends of the base portion 61 in a direction orthogonal to the detection resonating arms 62a and 62b, respectively; a pair of driving resonating arms 67a and 67b and 70a and 70b protruding from the distal end portions of the respective connecting arms 65a and 65b in both directions orthogonal to the connecting arms 65a and 65b, respectively.

The respective detection resonating arms 62a and 62b and the respective driving resonating arms 67a, 67b, 70a, and 70b have weight portions 64a and 64b and 69a, 69b, 72a, and 72b which are formed in the distal end portions and have a larger width than the width of the detection resonating arms 62a and 62b and the driving resonating arms 67a, 67b, 70a, and 70b, respectively. A plurality of frequency adjustment slits 25 penetrating through the front and rear surfaces of each of the weight portions 64a, 64b, 69a, 69b, 72a, and 72b so as to extend in a straight line form along the longitudinal direction of the respective resonating arms are formed in the weight portions 64a, 64b, 69a, 69b, 72a, and 72b.

Furthermore, the excitation electrodes (not shown) of the resonating gyro device 4 are formed on each of the front and rear surfaces of at least the pair of detection resonating arms 62a and 62b and the pair of driving resonating arms 67a, 67b, 70a, and 70b. In addition, lead electrodes are formed so as to electrically connect electrode pads (not shown) formed on the base portion 61.

FIG. 7B is a schematic plan view illustrating the operation of the resonating gyro device 4. When no angular velocity is applied to the resonating gyro device 4, the driving resonating arms 67a, 67b, 70a, and 70b perform flexural vibration in a direction indicated by arrows E. In this case, since the driving resonating arms 67a and 67b and the driving resonating arms 70a and 70b perform vibration in a linearly symmetrical manner about the Y axis that passes the center G, the base portion 61, the connecting arms 65a and 65b, and the detection resonating arms 62a and 62b are hardly vibrated.

When an angular velocity ω around the Z axis is applied to the resonating gyro device 4, the Coriolis' force acts on the driving resonating arms 67a, 67b, 70a, and 70b and the connecting arms 65a and 65b, whereby new vibration is excited. This vibration is vibration which act in the circumferential direction to the center G. At the same time, in response to the vibration, detection vibration is excited in the detection resonating arms 62a and 62b. A distorsion generated by this vibration is detected by detection electrodes formed in the detection resonating arms 62a and 62b, and the angular velocity is calculated.

Weight portions having a larger width than the width of the detection resonating arms and the driving resonating arms are formed in the distal end portions of the detection resonating arms and the driving resonating arms, and frequency adjustment slits are formed in the weight portions. Since the respective resonating arms are excited by flexural vibration, it is possible to greatly decrease the deviation from a predetermined frequency due to over-etching when forming the shape of the piezoelectric substrate by an etching method.

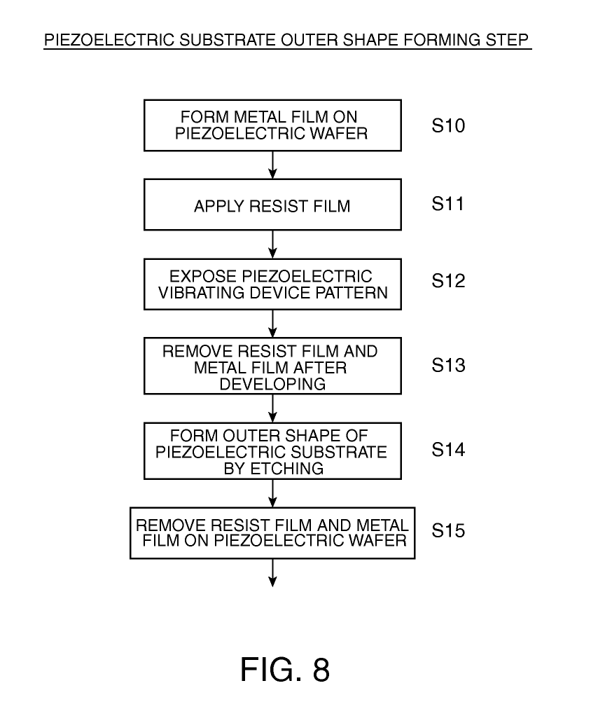

FIGS. 8, 9, and 10 are flowcharts showing manufacturing steps relating to forming of the shape and slits of the piezoelectric substrate, the groove portions, and the excitation electrodes of the piezoelectric resonators 1 to 4 shown in FIGS. 1A and 1B, 5A and 5B, 6A and 6B, and 7A and 7B, respectively.

FIG. 8 is a flowchart showing manufacturing steps for forming the shape (outer shape or outline) and the frequency adjustment slits of the piezoelectric resonators 1 to 4. In step S10, a metal film such as a film of Cr and Au is formed on the entire surface of a piezoelectric wafer (quartz crystal wafer) by deposition, sputtering, or the like.

In step S11, a photoresist film (referred to as a resist film) is applied on the entire surface of the metal film. In step S12, a resist film in which a mask pattern corresponding to frequency adjustment slits and the outer shape are formed on both the front and rear surfaces thereof is exposed using an exposure device.

In step S13, the resist film is developed to remove the exposed resist film. In addition, when the metal film exposed from the resist film is removed by dissolving using a predetermined solution, a piezoelectric wafer in which a number of patterns corresponding to the frequency adjustment slits and the outer shape of a piezoelectric substrate are formed is obtained.

In step S14, the piezoelectric wafer exposed from the resist film and the metal film is subjected to wet-etching using a hydrofluoric solution so that the outer shape of a piezoelectric substrate having desired frequency adjustment slits is obtained.

In step S15, a redundant resist film and a redundant metal film are removed, whereby a piezoelectric substrate having a desired shape is obtained. The piezoelectric substrate having a desired shape and the piezoelectric wafer are connected by supporting pieces and are not separated from each other.

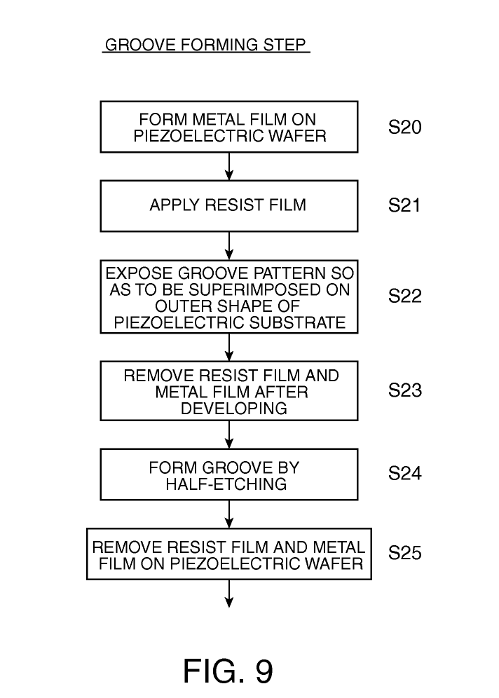

FIG. 9 is a flowchart showing a manufacturing step of forming groove portions in resonating arms. In step S20, as described in FIG. 8, a metal film is formed on the entire surface of a piezoelectric wafer in which the outlines of a piezoelectric substrate having frequency adjustment slits are arranged in a grid form. In step S21, a resist film is applied on the entire surface.

In step S22, a groove pattern is exposed on the resist film on the front and rear surfaces using a groove mask corresponding to groove portions to be formed. In step S23, after developing the resist film, the exposed resist film is removed, and the metal film exposed from the resist film is dissolved.

In step S24, the piezoelectric substrate exposed from the resist film so as to correspond to the groove portions is subjected to half-etching. In step S25, a redundant resist film and a redundant metal film are removed.

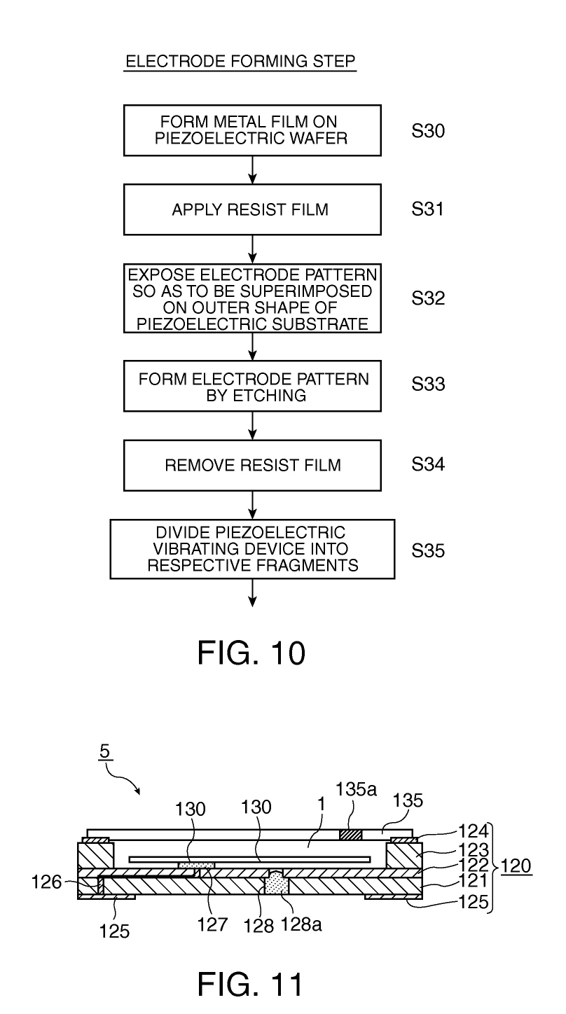

FIG. 10 is a flowchart showing a manufacturing process of forming excitation electrodes. In step S30, a metal film is formed by deposition, sputtering, or the like in order to form excitation electrodes or the like on the entire surface of a piezoelectric substrate. In step S31, a resist film is applied on the entire surface.

In step S32, an electrode pattern is exposed to the resist film on both the front and rear surfaces using a photomask corresponding to the electrode pattern. In step S33, after developing the resist film, an exposed resist film is removed. Moreover, the metal film exposed from the resist film corresponding to the electrode pattern is dissolved.

In step S34, the resist film is removed. In this case, piezoelectric resonating devices in which excitation electrodes or the like are formed at a predetermined position of the piezoelectric substrate are formed. In step S35, supporting pieces connecting the piezoelectric wafer and the piezoelectric resonating devices are broken, and the piezoelectric resonating devices are divided from the piezoelectric wafer.

In the above description, although the manufacturing steps of the piezoelectric resonating devices 1 to 3 have been described, the manufacturing steps relating to forming of the outer shape, the frequency adjustment slits, and the excitation electrodes of the resonating gyro device 4 are the same as the above. Thus, redundant description thereof will not be provided.

By using the manufacturing method, it is possible to greatly decrease the deviation from a predetermined frequency due to over-etching when forming the shape of a piezoelectric substrate for a tuning-fork type piezoelectric resonating device by etching.

By using the manufacturing method to the resonating gyro device, it is possible to greatly decrease the deviation from a predetermined frequency due to over-etching when forming the shape of a piezoelectric substrate for a resonating gyro device by etching.

FIG. 11 is a cross-sectional view showing the configuration of a piezoelectric resonator including any one of the above piezoelectric resonating devices 1 to 3 and a package in which any one of the piezoelectric resonating devices 1 to 3 is accommodated. The package includes a package body 120 formed in a rectangular box shape and a lid member 135 having a window member 135a formed of a glass or the like.

As shown in FIG. 11, the package body 120 is formed by stacking a first substrate 121 as an insulating substrate, a second substrate 122, and a third substrate 123. A ceramic green sheet formed of an aluminum oxide as an insulating material is molded into a box shape and sintered to form the package body 120. A plurality of mount terminals 125 is formed on the outer bottom surface of the first substrate 121.

The third substrate 123 is an annular body with the central portion removed, and a metal seal ring 124 formed of a kovar, for example, is formed on the upper cirference of the third substrate 123.

A recess portion in which the piezoelectric resonating device 1 is accommodated is formed by the third substrate 123 and the second substrate 122. A plurality of device mounting pads 127 which is electrically connected to the mount terminals 125 by a conductor 126 is formed at a predetermined position on the upper surface of the second substrate 122.

The device mounting pads 127 are disposed so that the positions thereof correspond to the pad electrodes (not shown) formed on the L-shaped supporting portions 12b and 12c when the piezoelectric resonating device 1 is mounted.

When manufacturing the piezoelectric resonator 5, first, an appropriate amount of a conductive adhesive agent 130, for example, any one of an epoxy-based adhesive agent, a polyimide-based adhesive agent, and a bismaleimide-based adhesive agent, is applied to the device mounting pads 127 of the package body 120, and the piezoelectric resonating device 1 is placed thereon to apply a load.

The package is loaded into a hot furnace of a predetermined temperature in order to harden the conductive adhesive agent 130 in the piezoelectric resonator 1 mounted on the package body 120. After performing an annealing process, a laser beam is irradiated from the above to evaporate a part of a frequency adjustment metal film formed on the resonating arms to roughly adjust the frequency. The lid member 135 having the glass window member 135a is seam-welded to the seal ring 124 formed on the upper surface of the package body 120.

A heat treatment is performed before sealing through holes 128 of the package. The package is reversed upside down, and spherical filling materials 128a composed of metal balls are placed on the steps in the through holes 128. A gold-germanium allow or the like may be used as the filling materials 128a. The filling materials 128a are dissolved by irradiating a laser beam, and the through holes 128 are sealed, and the inside of the package is evacuated. A laser beam is irradiated into the package from outside the package through the window member 135a to evaporate the frequency adjustment metal film formed on the resonating arms to finely adjust the frequency. In this way, the piezoelectric resonator 5 is formed.

The resonating gyro sensor formed by accommodating the resonating gyro device 4 in the package can be formed by the same method as the piezoelectric resonator 5, and redundant description thereof will not be provided.

As above, the piezoelectric resonator includes a piezoelectric resonating device which includes a piezoelectric substrate including a base portion, a plurality of rod-shaped resonating arm, weight portions having a large width, formed in the respective resonating arms, frequency adjustment slits formed in the respective weight portions, and groove portions formed on the front and rear surfaces of each of the resonating arms, and excitation electrodes arranged on the front and rear surfaces of each of the resonating arms, and a package in which the piezoelectric resonating device is accommodated.

Since the frequency adjustment slits are formed in the weight portion having a large width, even if etching time exceeds a desired etching time, that is, over-etching occurs, when forming the shape of the piezoelectric substrate by etching, a decrease in the resonance frequency of tuning-fork vibration due to a decrease in the width of the respective resonating arms is canceled by an increase in the resonance frequency due to an increase in the width of the frequency adjustment slits. Thus, it is possible to greatly decrease the deviation from a predetermined frequency due to over-etching. Furthermore, by forming the weight portions, it is possible to miniaturize the piezoelectric resonator.

Moreover, the resonating gyro sensor includes a resonating gyro device including a base portion, a pair of detection resonating arms, a pair of connecting arms, a pair of driving resonating arms, weight portions having a large width provided in each of the distal end portions of the detection resonating arms and the driving resonating arms, and frequency adjustment slits formed in the weight portions, and a package in which the resonating gyro device is accommodated.

Since the respective resonating arms are excited by flexural vibration, by forming the frequency adjustment slits, it is possible to greatly decrease the deviation from a predetermined frequency due to over-etching when forming the shape of the piezoelectric substrate by an etching method.

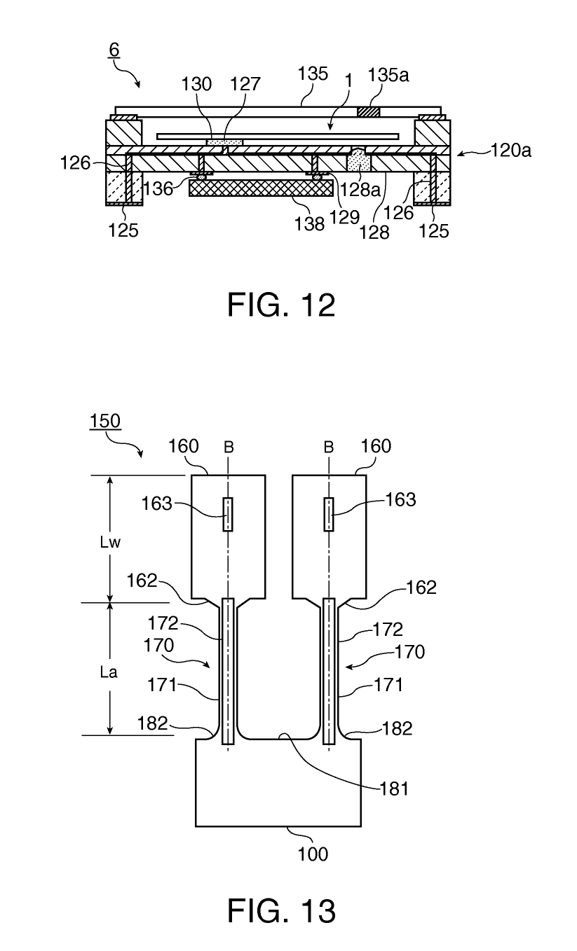

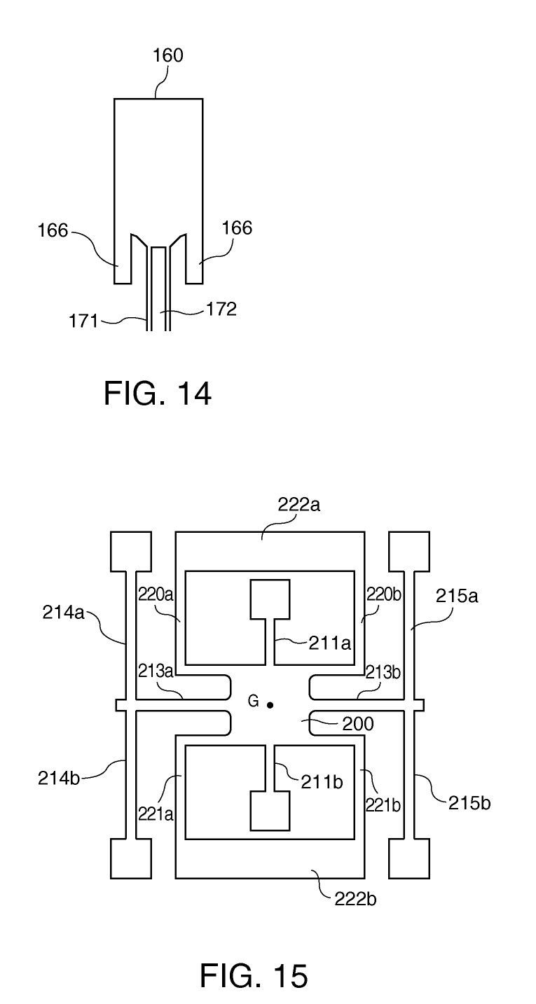

FIG. 12 is a cross-sectional view showing the configuration of a piezoelectric oscillator 6. The piezoelectric oscillator 6 includes any one of the above piezoelectric resonating devices 1 to 3, an IC component 138 that excites any one of the piezoelectric resonating devices 1 to 3, a package 120a in which any one of the piezoelectric resonating devices 1 to 3 is vacuum-sealed, and the IC component 138 is accommodated, and a lid member 135 having a window member 135a. The method of performing rough and fine adjustment by irradiating a laser beam to the piezoelectric resonating device, the method of evacuating the inside of the package to seal the through holes 28, and the like are the same as those of the piezoelectric resonator 5, and redundant description thereof will not be provided. The IC component 138 is electrically connected to the IC component mounting pads 129 of the package 120a using metal bumps 136 or the like.

Although an example in which the IC component 138 is not air-tightly sealed is shown in the cross-sectional view of the piezoelectric oscillator 6 shown n FIG. 12, the IC component 138 may be disposed inside the package and be air-tightly sealed.

The piezoelectric oscillator includes the piezoelectric resonating device, the IC component that excites the piezoelectric resonating device, and the package in which the piezoelectric resonating device and the IC component are accommodated. With this configuration, it is possible to obtain a piezoelectric oscillator which has a small size and little unnecessary vibration, and in which a frequency adjustment amount of the piezoelectric resonating device is small.

The cross-sectional view of an example of a resonating gyro apparatus is the same as that of FIG. 12, and redundant description thereof will not be provided.

The resonating gyro apparatus includes the resonating gyro device 4, an IC component that excites the driving resonating arms 67a, 67b, 70a, and 70b of the resonating gyro device 4 and detects and processes the frequency of the detection resonating arms 62a and 62b, and a package in which the resonating gyro device 4 is air-tightly sealed, and the IC component is accommodated.

The resonating gyro apparatus includes the resonating gyro device, the IC component that excites the driving resonating arms of the resonating gyro device and detects and processes the frequency of the detection resonating arms, and the package in which the resonating gyro device and the IC component are accommodated. Since the respective resonating arms are excited by flexural vibration, it is possible to greatly decrease the deviation from a predetermined frequency due to over-etching when forming the shape of the piezoelectric substrate by an etching method. Moreover, since the frequency adjustment slit are provided, it is possible to obtain a resonating gyro apparatus in which the frequency adjustment amount of the resonating gyro device is small, and which has a small size and little unnecessary vibration.

The entire disclosure of Japanese Patent Application No. 2010-269063, filed Dec. 2, 2010 is expressly incorporated by reference herein.

What is claimed is:

1. A piezoelectric resonating device comprising:
a plurality of rod-shaped resonating arms; and
a base portion that connects one set of end portions of the respective resonating arms,
wherein a plurality of slits is formed on the other set of end portions of the resonating arms.

2. The piezoelectric resonating device according to claim 1,
wherein the respective slits have the same longitudinal dimension, and the positions of both end portions in the longitudinal direction are identical to each other.

3. The piezoelectric resonating device according to claim 1,
wherein the respective slits have the same longitudinal dimension, and the positions of both end portions in the longitudinal direction are alternatively shifted from each other.

4. The piezoelectric resonating device according to claim 1,
wherein the respective slits have the same longitudinal dimension, and the width dimensions thereof are different from each other.

5. The piezoelectric resonating device according to claim 1,
wherein the respective slits include a plurality of sets of slits in which one set of end portions in the longitudinal direction of two adjacent slits are connected by a connecting slit.

6. The piezoelectric resonating device according to claim 1,
wherein one set of end portions of the respective slits are open to an end of the weight portion.

7. The piezoelectric resonating device according to claim 1,
wherein the respective slits are formed so as to be symmetrical to a center line of vibration of the piezoelectric substrate.

8. The piezoelectric resonating device according to claim 1,
further comprising a weight portion formed on the other end portions, and the slits are formed in the weight portion.

9. The piezoelectric resonating device according to claim 1,
wherein the piezoelectric resonating device is a resonating gyro device.

10. A piezoelectric resonator comprising:
the piezoelectric resonating device according to claim 1; and
a package in which the piezoelectric resonating device is accommodated.

11. A piezoelectric resonator comprising:
the piezoelectric resonating device according to claim 2; and
a package in which the piezoelectric resonating device is accommodated.

12. A piezoelectric resonator comprising:
the piezoelectric resonating device according to claim 3; and
a package in which the piezoelectric resonating device is accommodated.

13. A piezoelectric resonator comprising:
the piezoelectric resonating device according to claim 4; and
a package in which the piezoelectric resonating device is accommodated.

14. A piezoelectric oscillator comprising:
the piezoelectric resonating device according to claim 1;
an IC component that excites the piezoelectric resonating device; and
a package in which the piezoelectric resonating device is air-tightly sealed, and the IC component is accommodated.

15. A piezoelectric oscillator comprising:
the piezoelectric resonating device according to claim 2;
an IC component that excites the piezoelectric resonating device; and
a package in which the piezoelectric resonating device is air-tightly sealed, and the IC component is accommodated.

16. A piezoelectric oscillator comprising:
the piezoelectric resonating device according to claim 3;
an IC component that excites the piezoelectric resonating device; and
a package in which the piezoelectric resonating device is air-tightly sealed, and the IC component is accommodated.

17. A piezoelectric oscillator comprising:
the piezoelectric resonating device according to claim 4;
an IC component that excites the piezoelectric resonating device; and
a package in which the piezoelectric resonating device is air-tightly sealed, and the IC component is accommodated.

18. A method of manufacturing a piezoelectric resonating device which include
a plurality of rod-shaped resonating arms,
a base portion that connects one set of end portions of the respective resonating arms,
groove portions formed on each of a front surface and a rear surface of each of the resonating arms, and
excitation electrodes formed on the front and rear surfaces of each of the resonating arms,
in which a plurality of slits is formed on the other set of end portions of the resonating arms, the method comprising:
forming the outer shape of the piezoelectric resonating device and the slits by etching;
forming the groove portions by etching; and
forming the excitation electrodes.

19. The method of manufacturing the piezoelectric resonating device according to claim 18,
wherein the piezoelectric resonating device is a resonating gyro device.
